(19) United States
(12) Patent Application Publication
(10) Pub. No.: US 2009/0250687 A1
(43) Pub. Date: Oct. 8, 2009

(54) SEMICONDUCTOR DEVICE AND METHOD TO CONTROL THE STATE OF A SEMICONDUCTOR DEVICE AND TO MANUFACTURE THE SAME

(76) Inventors: Boris A. Plamenevsky, St. Petersburg (RU); Lev M. Baskin, St. Petersburg (RU); Pekka Neittaanmaki, Jyvaskyla (FI)

Correspondence Address: FILDES & OUTLAND, P.C., 20916 MACK AVENUE, SUITE 2, GROSSE POINTE WOODS, MI, 48236, US

(21) Appl. No.: 12/417,382

(22) Filed: Apr. 2, 2009

(30) Foreign Application Priority Data
Apr. 3, 2008 (FI) 20085278

(51) Int. Cl. H01L 29/12; H01L 29/66; H01L 21/335

(52) U.S. Cl. 257/24; 438/142; 257/E29.069; 257/E29.168; 257/E21.4; 257/25

(57) ABSTRACT

A semiconductor device includes a conduct structure to which are arranged contacts for a source and a drain, a resonance region including at least two barrier regions, at least one resonator between the barrier regions and a control electrode and which resonance region is arranged between the contacts. The conduct structure between the contacts is homogeneous and the barrier regions are formed of narrows arranged to the conduct structure. In addition, disclosed are methods to control the state of a semiconductor device and manufacture the same.

### FIELD OF THE INVENTION

The invention concerns a semiconductor device comprising a conduct structure to which is arranged
contacts for a source and a drain and
a resonance region including at least two barrier regions forming at least one resonator and a control electrode and which resonance region is arranged between the contacts.

In addition, the invention also concerns method to control the state of a semiconductor device and to manufacture the same.

### BACKGROUND OF THE INVENTION

Three terminal semiconductor devices, including a resonance region between two barriers, are generally known from the prior art. Such devices implementing both digital and analog circuits result from the need for increased miniaturization, functional density, and operating speed, particularly where nanosize and mesoscopic regimes are concerned.

As is well known, a quantum well structure as a resonance region is comprised of a layered semiconductor structure in which the quantum well layer is sandwiched between two barrier layers of semiconductor or insulator material with larger conduction energy band than that of the quantum well layer. Incoming electrons tunnel resonantly through the barriers and quantum well when the resonant energy states inside the quantum well are favourably aligned with the energy of the electrons.

The resonant energy level inside the quantum well acts as a filter of the electrons. The energy level of the resonant state within the quantum well places a restriction on the value of momentum in the direction of propagation for the electrons which are transmitted through the quantum well barriers, instead of being reflected. As a result, only the electrons having a narrow range of momentum values in the propagation direction will be transmitted through the barriers.

If the resonant energy level in the quantum well is below the conduction band edge and above the valence band edge of the source of electrons outside the barriers, no current can flow through the quantum well. These devices have a third electrode controlling the quantum well resonant energy level, so they are resonant tunnelling transistors. However, limited success has been achieved in manufacturing such devices because of the great difficulty in making barriers or in indirectly influencing the resonant level without affecting the outside semiconductor layers.

From the prior art is known a transistor element that is based on the resonance region implementation. This kind of element has been presented in US Statutory Invention Registration H1570. In that the quantum well region is disposed between the source and the drain electrodes and separated from the source and the drain by barrier regions. In the barrier region, the electron potential energy is higher than those in the source, drain, or quantum well between the barriers. The barrier region is created by shifting the conduction energy band, which can be implemented by changing the semiconductor material in the barrier region or by a voltage on a metal element on the surface.

This kind of structure causes challenges concerning, for example, the manufacture of the element. In the device, the barriers which are part of the resonance region have to be made of a material which differs from the rest part of the element. Owing to this, the device is inhomogeneous. Otherwise, additional electrodes are needed to impose a voltage creating the potential barriers.

### SUMMARY OF THE INVENTION

The purpose of the present invention is to provide an improvement in resonant tunnelling semiconductor devices and, more particular, to bring about a way to implement a semiconductor device which has a simple construction and thus its fabrication is easy. The characteristic features of the device according to the invention are presented in the appended claim 1, the characteristic features of the method to control a state of a semiconductor device are presented in claim 10 and the characteristic features of the method to manufacture a semiconductor device are presented in claim 11.

In the invention has been applied a new way to create the barriers. In the semiconductor device, according to the invention, the barrier regions, being included in the resonance region, are narrows arranged to the conduct structure. The narrows locally narrow the cross-sectional diameter of the conduct structure.

The narrows separate the resonance region from the source and the drain contacts. Owing to the narrows, there is no need for an outer voltage in order to arrange the barrier functionality.

The conduct region between the source and the drain contacts including the resonance region is homogeneous in the semiconductor device according to the invention. Thus, the functionalities of the conduct region may be fabricated from a single material. Owing to this feature there are not any band offsets between the parts of the conduct region. This is an essential advantage because it provides the significant ease of fabrication, reproducibility and as well as advantages in the operation ability. In addition, the structure according to the invention allows avoiding incoherent scattering by the barrier border.

According to the invention, to control the device there is arranged an electrode means providing a potential field in the resonance region. The field changes the electron energies in at least one resonator and thus controls the resonant energy level and tunnelling of the electrons from the source to the drain contacts.

Owing to the invention several other considerable advantages have also been achieved in addition to the ease of fabrication. The device according to the invention is small in size. In addition to the scale aspects, the device has the important advantage of small thermal losses. The length of the conduct does not exceed the electron free path. This means that the device operates within the so-called ballistic regime.

The device has also a high frequency operating range. It may be, for example, 10¹¹-10¹² Hz. Stable operating under heating doesn't limit the application of the device to some special temperature conditions.

The device according to the invention has several applications. That can be used, for example, as an element of high frequency integral circuits. Other characteristic features of the invention will emerge from the appended Claims, and more achievable advantages are listed in the specification.

### BRIEF DESCRIPTION OF THE DRAWINGS

The invention, which is not limited to the embodiments to be presented in the following, will be described in greater detail by referring to the appended figures, wherein

FIG. 1 shows an example of a semiconductor device with one resonator as an axial section,

FIG. 2 shows a zone scheme of the semiconductor device presented in FIG. 1,

FIG. 3 shows an example of the dependence of the current J_{sd} between the source and the drain contacts on the control voltage U_{c} for the semiconductor device presented in FIG. 1,

FIG. 4 shows a second example of the semiconductor device equipped with two resonators as an axial section,

FIG. 5 presents a zone scheme of the semiconductor device presented in FIG. 4,

FIG. 6 shows an example of the dependence of the current J_{sd} between the source and the drain contacts on the control voltage U_{c} for the semiconductor device presented in FIG. 4,

FIG. 7 shows an example of geometry of a resonator with two narrows, the axial section of a 3D axially symmetric conduct structure,

FIG. 8a shows an example for the transition coefficient for the conduct structure and

FIG. 8b shows an example of the electron density distribution.

### DETAILED DESCRIPTION OF THE INVENTION

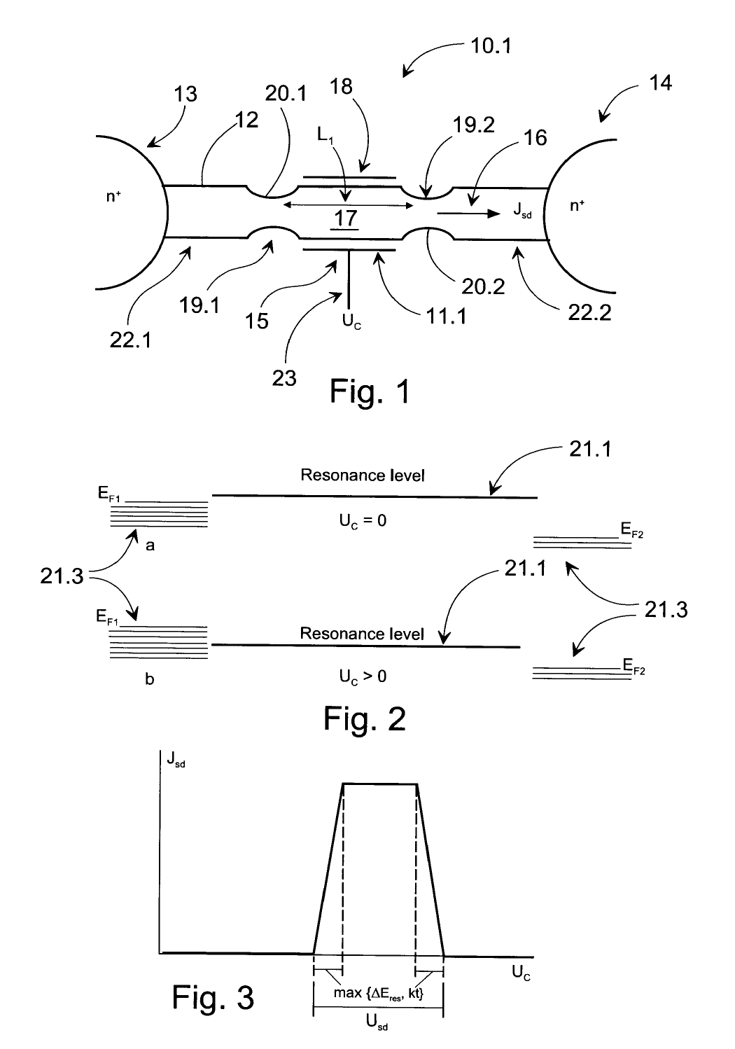

FIG. 1 shows a principle of the first embodiment of the semiconductor device 10.1 according to the invention. The device 10.1 may be, for example, a current controller (i.e. an amplifier unit, like a transistor) or a key unit. One skilled in the art appreciates that the different embodiments of the devices 10.1, 10.2 according to the invention may also have other applications than specified in this application.

The device 10.1 operates on a resonant tunnelling principle, the basic phenomena of which are generally well known in the art. The semiconductor device 10.1 may be formed of a thin conduct structure 12, contacts 13, 14 to the conduct structure 12 and a quantum resonance region 15, which is a part of the conduct structure 12. The diameter of conduct's 12 cross-section may be, for example, about 10 nm, more general 5-50 nm. The conduct structure may be, for example, a quantum wire or a quantum waveguide structure 12 manufactured of a high-resistivity semiconductor or of a dielectric and operating within the ballistic regime. In this kind of collisionless conditions the critical sizes of the conduct 12 are not greater than the electron free path. This means that there will not appear electron collisions. Ballistic regime exists only at low temperature where the electric conductivity is a quantum phenomenon.

In connection with the conduct structure 12 have been arranged a source electrode contact 13 (cathode) and a drain electrode contact 14 (anode). The source and the drain maintaining the electron transport in a quantum wire 12 have not been presented herein and the type of those can be any kind of. The source and the drain maintain a voltage difference along the wire 12. The contacts 13, 14 are now located at the opposite ends of the elongated wave conduct structure 12 that is the conduct region between them.

The quantum resonance region 15 arranged between the contacts 13, 14 i.e. to the conduct region is equipped with a control electrode 18 being a metal gate element. The purpose of the control electrode 18 is to control the state and function of the device 10.1. More particular, by the gate electrode 18 that is near to the resonance region 15 is provided a control potential voltage U_{c} for the resonance region 15. In connection with the gate 18 is arranged a terminal contact 23 for supplying a potential U_{c} to the resonance region 15.

The quantum resonance region 15 i.e. a quantum well in order to initiate electron resonant tunneling includes now one resonator 11.1. The resonator 11.1 is formed of two local narrows 20.1, 20.2 arranged to the conduct structure 12 at both ends of the resonance region 15 i.e. between the contacts 13, 14. A pair of elongated regions 22.1, 22.2 extends outwardly from the barrier regions 19.1, 19.2 being now the contractions 20.1, 20.2 of the wire 12. The full length of the conduct structure 12 between the contacts 13 and 14 is smaller than the electron wave function coherence length and the electron free path. The length of the conduct 12 may be, for example, less than 100 nm, for example, 10-100 nm.

The material of the conduct 12 and its cross-section diameter is arranged to be such that the electric field generated by the control electrode 18 penetrates into the quantum resonator domain 17. This means that the diameter of the conduct 12 is no greater than the Debay length (1 nm-1 mm). This means that the lateral sizes of the source contact region 13, the drain contact region 14, the quantum resonance region 15, and the barrier regions 19.1, 19.2 are all smaller than the electron wave function coherence length in either one or two dimensions. Therefore, varying the control voltage U_{c} of the gate electrode 18, it is possible to change the energies of the electrons or, in other words, the resonance level of the resonance region 15, which causes changing current in the wire 12. The resonator length remains unchangeable.

The contacts 13 and 14 can be made of, for example, a heavily doped n-type crystal or of a metal. The contacts 13, 14 can, when desirable, further include layers of metallization as well as voltage terminals. Between the source and the drain contacts 13, 14 there is a difference of potentials U_{sd} giving rise to the directed electron wave 16 going along the conduct structure 12 from the source contact 13 to the drain contact 14. The magnitude of the potentials can be 0.1-0.5 V, for example.

The narrows 20.1, 20.2 which narrow the cross-sectional diameter of the conduct structure 12 are effective barriers for the motion of the electrons going along the conduct structure 12. The barrier effect of the narrows 20.1, 20.2 has been disclosed hereinafter in the theoretical background of this application. The barrier regions 19.1, 19.2 are of the same material as the whole of the conduct structure 12. In other words, the conduct structure 12 between the contacts 13, 14 may be homogeneous structure which provides significant advantages. That simplifies the structure of the device 10.1 and provides also advantages in the form of easier manufacture. In addition, such a simple way of implementing the barriers 19.1, 19.2 allows avoiding the incoherent scattering from the barrier borders.

Since the resonator 11.1 has a definite size, the resonant states of the electron inside the resonator unit 11.1 are fixed with discrete resonant energy levels. Tunnelling from the source contact 13 to the drain contact 14 through the resonance region 15 is most probable through these resonant energy states. When the occupied energy subband of the electron source 13 coincides with a resonance region 15 resonant energy level, there is a large tunnelling probability and hence a large tunnelling current. When the resonant energy level of the resonance region 15 is not aligned with the occupied subband energy of the source 13, there is a low tunnelling current. The resonant energy level of the resonance region 15 is controlled by the electrostatic potential field U_{c}. Changing the electrostatic potential field by using the third electrode 18 changes the resonant energy level of the resonance region 15, which can be moved into and out of the occupied subband in the source contact 13, turning the tunnelling current on and off.

FIG. 2 presents a zone scheme of the device 10.1 with one resonator 11.1. The geometry of the resonator 11.1 like, for example, the axial length L₁ determines the resonance level 21.1 that is the energy of the electrons which can tunnel through the resonator 11.1 from the source contact 13 to the drain contact 14 with a probability close to 1. Like the upper part (a) of FIG. 2 indicates, in the device 10.1 the length L₁ of the domain 17 of the resonator 11.1 has been chosen so that at zero potential U_{c}=0 of the control electrode 18 the lowest resonance energy level 21.1 of the resonator 11.1 is higher than the maximal electron energy E_{F1} (Fermi level) in the source contact 13 and hence there is no current between the source and the drain contacts 13, 14. In addition, the lowest resonance energy level 21.1 of the resonator 11.1 is also higher than the maximal electron energy E_{F2} (Fermi level) in the drain region 14. Thus, if the control voltage U_{c} is equal to zero, then due to the length L₁ of the resonator 11.1 the electron transmission probability through the conduct 12 is negligible for all the electrons approaching the resonator 11.1 (since the electron energy E<E_{F1} for all the electrons); therefore the current J_{sd} is negligible as well (FIG. 3).

FIG. 3 presents a dependence of the current J_{sd} between the contacts 13, 14 on a control voltage U_{c}. Under a voltage U_{c}>0 at the control electrode 18, the resonance level 21.1 of the resonator 11.1 becomes lower and for some critical voltage Uᵣₑₛ the resonance level Eᵣₑₛ coincides with the maximal electron energy E_{F1} at the source 13. In other words, a current arises when the resonant level coincides with an occupied level in the cathode and empty state in the anode. The control voltage U_{c} may be, for example, 0.05-0.5 V. Owing to this there arises the current J_{sd} between the source and the drain contacts 13, 14.

The amount of current J_{sd} depending on U_{sd} may be, for example, 1-10 nA. In other words changes of the resonance condition effectively modulate the output current J_{sd} of the device 10.1. On increasing the control voltage U_{c}, the current J_{sd} remains practically invariable because it involves electrons with energy in an interval whose width is constant and is determined by the width of the resonance level 21.1. On further increasing the voltage U_{c} of the control electrode 18, the resonance level Eᵣₑₛ coincides with the maximal electron energy E_{F2}=E_{F1}−eU_{sd} in the drain contact 14. Owing to this, the current J_{sd} vanishes because all the final states for the electrons have been occupied. The width of the transition region and max{ΔEᵣₑₛ, kT} are of the same order in magnitude, where ΔEᵣₑₛ is the width of the resonance peak and kT is the thermal dispersion of electron energies at a contact, T being a temperature at the contact.

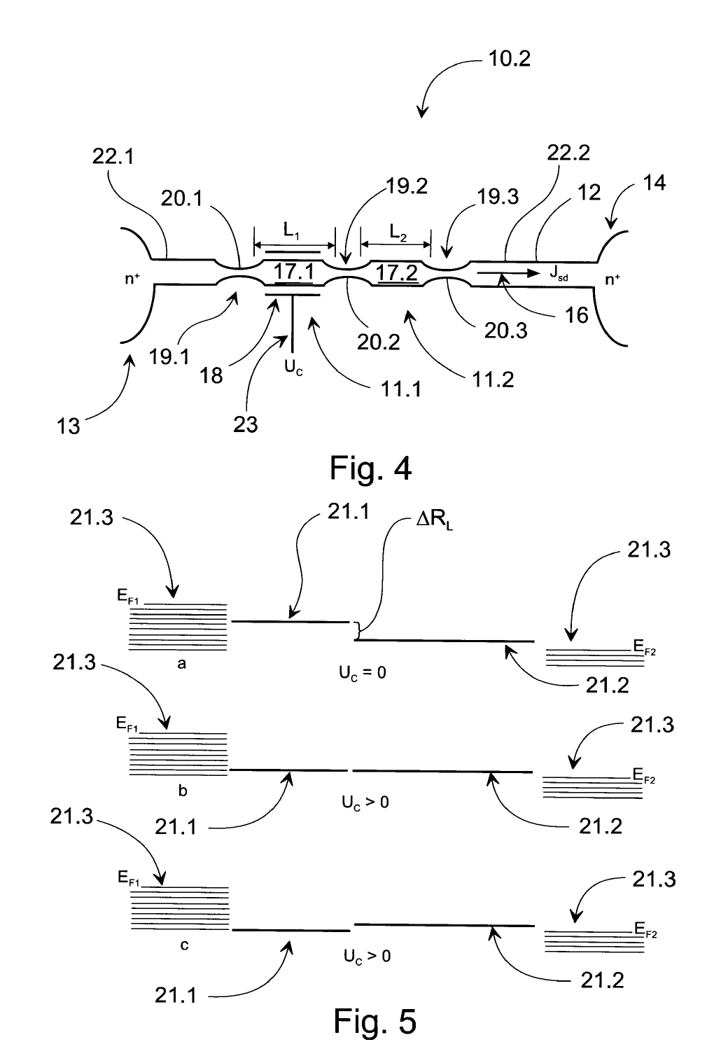

The semiconductor device 10.2 presented in FIG. 4 implements a principle of a semiconductor component according to the second embodiment. The reference signs of the device 10.2 correspond to the device 10.1 presented above. The quantum resonance region 15 is again a part of the conduct structure 12 and now it includes two resonators 11.1 and 11.2 and three narrows 20.1-20.3 being the effective barriers 19.1-19.3 arranged to the conduct structure 12. Three narrows 20.1-20.3 give a pair of successive resonators 11.1, 11.2. In order to create two separate resonators the conduct 12 may include four narrows, etc.

Between the source and the drain contacts 13, 14 is a resonance region 15 which includes now two resonator domains 17.1 and 17.2 and control electrode 18 (gate) on the side of the wire 12 close to a resonator 11.1. One of the resonators 11.1 is arranged to be more on the effect of the gate electrode 18 than the other resonator 11.2. Generally speaking, the gate electrode 18 is arranged to effect the resonators 11.1, 11.2 in an unbalanced manner. The control electrode 18 is arranged near to the resonator 11.1. Thus, in this case the control electrode 18 is arranged to control the resonance level 21.1 of one of the resonators 11.1 and the resonance level 21.2 of the other resonator 11.2 is fixed.

The narrow regions 20.1, 20.3 being the effective barriers 19.1, 19.3 are at both ends of the resonance region 15 and the narrow region 20.2 is between the resonators 11.1, 11.2. The narrows 20.1-20.3 form the barriers 19.1-19.3 for the electrons coming along the conduct structure 12. Thus, the barrier regions 19.1-19.3 are of the same material as the conduct structure 12 and the resonators 11.1, 11.2. This simplifies the structure of the device 10.2 and gives advantages of easier manufacture.

FIG. 5 presents a zone scheme of a device 10.2 equipped with two resonators 11.1, 11.2. The resonance energy level 21.1 of the resonator 11.1 differs a little from that of resonator 11.2. In the device 10.2 the geometry of resonators 11.1, 11.2, like the lengths L₁,L₂ of the domains 17.1, 17.2 are chosen so that the electron resonance level 21.1, 21.2 of the resonators 11.1, 11.2 are less than the maximal energy level E_{F1} of the electrons at the source contact 13. In addition, the electron resonance level 21.1, 21.2 of the resonators 11.1, 11.2 also are greater than the maximal energy level E_{F2} of the electrons at the drain contact 14, E_{F2}=E_{F1}−eU_{sd}. Moreover, the lengths L₁,L₂ of resonators 17.1, 17.2 are chosen so that the difference ΔR_{L}=Eᵣₑₛ₁−Eᵣₑₛ₂ of the resonance levels 21.1, 21.2 would be greater than the width of the resonance curve.

Owing to the above, there is no current J_{sd} between the source and the drain contacts 13, 14. Such a current arises if both of the following conditions are fulfilled:
1) the resonance levels 21.1, 21.2 of the resonators 11.1, 11.2 coincide, ΔR_{L}=0;
2) the common resonance level E_{R} satisfies E_{F2}<E_{R}<E_{F1}.

The condition 2 can be provided by choosing U_{sd}. For example the value U_{sd} can be chosen in the interval (0.1-1) V. Varying the voltage U_{c} of the control electrode 18, it is possible to change the level 21.1. If the control voltage U_{c}=0, then the current in the system is negligible because the resonance level 21.1 of the resonator 11.1 is different from that of resonator 11.2, like the upper part (a) of FIG. 5 indicates. At a critical U_{c} the level 21.1 at the resonator 11.1 coincides with the level 21.2 at the resonator 11.2 and the current J_{sd} arises between the source and the drain contacts 13, 14, like the middle part (b) of FIG. 5 indicates. On further increasing U_{c}, the levels 21.1 and 21.2 become distinct and the current vanishes, like the down part (c) of FIG. 5 indicates.

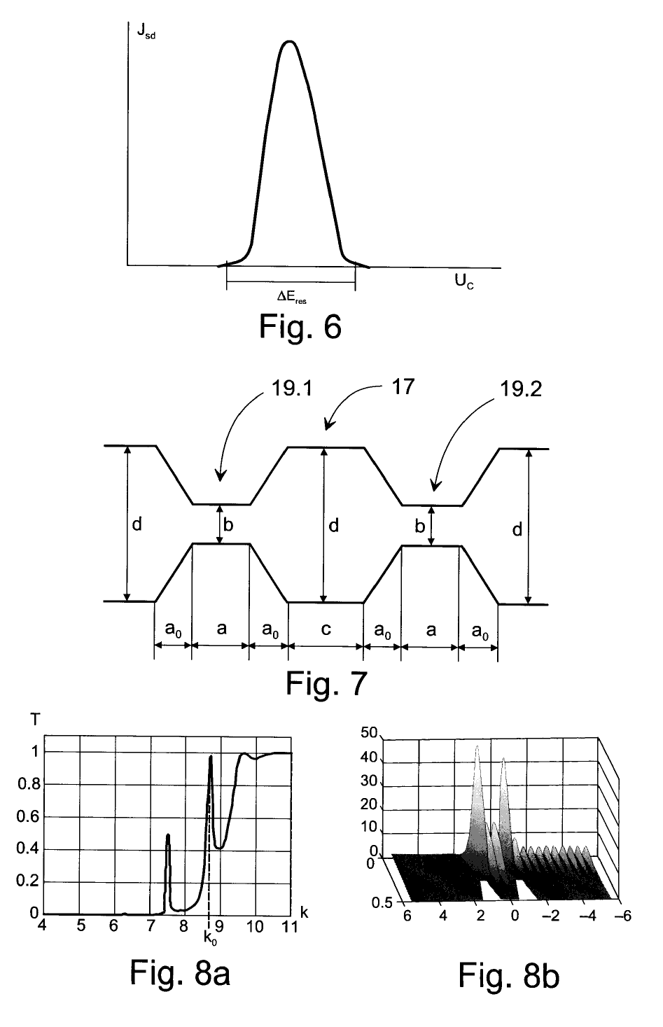

The dependence of J_{sd} on U_{c} has been shown in FIG. 6. In contrast to the device 10.1, for device 10.2 the interval of U_{c} corresponding to nonzero J_{sd} depends neither on T nor on U_{sd} and is determined only by the form of resonant curves. In other words, the device 10.2 is temperature independent that is a considerable advantage of this embodiment. Owing to this the device 10.2 is stable under heating within the ballistic regime.

In addition, it should also be notified that the advantage concerning the temperature independence has been achieved by applying two resonators 11.1, 11.2, not with narrows 20.1-20.3 as effective barriers. This means that the barrier regions may not necessarily be the narrows like stated above. Other suitable means to arrange the barrier regions may be traditional known from the prior art.

The conduct structure 12 of the devices 10.1, 10.2 including the barriers 19.1-19.3 being now the narrows 20.1-20.3 and resonator domains 17, 17.1, 17.2 shown and described herein can be fabricated of some suitable high-resistivity semiconductor material from Group III-V compounds and dielectric crystalline materials owing to which it operates within the ballistic regime. One example of such a material can be GaAs or TiN or diamond. It should be noted at the outset, however, that such devices are not limited to GaAs, TiN or diamond basis devices, but can, when desired, be formed from other types of semiconductor and insulating materials which exhibit resonant tunnelling operating characteristics. When desirable, the entire structure can be formed on an insulating or a semi-insulating substrate (not shown). The source and the drain contacts 13, 14 and the control electrode 18 are made of a metal or of a heavy doped semiconductor. The devices 10.1, 10.2 may be incorporated in planar, a multi-epilayered or bulk type integrated circuit technology.

The semiconductor device 10.1, 10.2 according to the invention can perform, for example, the operations of a conventional transistor or a key scheme device. Thus, it can function, for example, as a switch, an amplifier, an oscillator, etc. while being implemented in nanoelectronic and mesoscopic size regimes which can be used in both digital and analog circuits. The invention also concerns a high frequency integrated circuit comprising a semiconductor device presented above and also a manufacturing method in which the barrier regions 19.1, 19.2 are arranged by providing the narrows 20.1, 20.2 to the conduct structure 12.

Theoretical Background

Let's consider electron motion in a thin conducting wire 12 and assume the electron free path to be essentially greater than the length of the wire 12 (the so-called ballistic regime). It is well known that for a wave guide of circular cross-section, the electron energy E satisfies

$$E = \frac{{ℏ}^{2} {μ}_{n}^{2}}{2 m ⊥ {R}^{2}} ,$$

where R is the radius of section, m_{⊥} and m_{∥} are the transversal and the longitudinal effective electron masses, k_{∥} is the wave number characterizing the longitudinal electron motion and μₙ the n-th root of the equation J₀(x)=0.

If the waveguide's section is noncircular, then the above formula for E is not valid. However, as before,

$$E = {E}_{n ⊥} + \frac{{ℏ}^{2} {k}_{‖}^{2}}{2 {m}_{‖}} ,$$

while the transversal energy E_{n⊥} is quantized and E_{1⊥}<E_{2⊥}<E_{3⊥}< . . . . For the sake of simplicity, it is assumed that E_{1⊥}<E<E_{2⊥}.

It has been noticed that the local narrows 20.1-20.3 of a quantum waveguide 12 are effective barriers for the longitudinal electron motion. The occurrences of such a barrier 19.1-19.3 can be qualitatively explained in the following way. The full electron energy E equals E_{⊥}+E_{∥}, where E_{⊥} and E_{|} are the transversal and the longitudinal electron energies. When the section is slowly varying along the axis of the wire 12,

$${E}_{⊥} ( z ) \approx \frac{{ℏ}^{2}}{2 mS ( z )} ,$$

the S(z) being the cross-section at a point z of the axis; so the transversal energy E_{⊥} increases at the narrows. Since the full energy E remains constant, the longitudinal energy E_{∥} decreases, which can be taken as the emergence of an effective barrier for the longitudinal electron motion.

At a narrow of sufficiently small diameter, for example, (50-80)% of the original cross-sectional diameter, there occur the phenomena of reflection from and tunneling through the barrier, and, in the case of several narrows (more than one),—the phenomenon of resonant tunneling. Under resonant tunneling, the electrons of a certain energy E₀ go through the resonator 11.1, 11.2 with probability T=1. This happens, if the resonator 11.1 (the domain 17, 17.1 between two narrows 20.1, 20.2) is of a length L divisible by the electron wave length. The electrons of somewhat different energies have small transition probabilities. FIG. 7 shows an example of the axial section of a 3-dimensional axially symmetric waveguide 12 with two narrows 20.1, 20.2.

FIG. 8a presents the transition coefficient T for the waveguide with a₀=⅓, b=0.55, c=1, d=1. The wave number k is between the first and the second thresholds. FIG. 8b presents the distribution density |ψ|² of an electron wave for k₀=8.7. FIG. 8b presents the dependence of the transition probability T for k˜\sqrt{E}; the two peaks are caused by resonant tunneling. The barriers corresponding to the narrows are of height less than the electron energy with k≧9. Therefore such electrons go through the resonator 11.1. Under resonant tunneling, the module of the wave function sharply increases inside the resonator 11.1. The width of every resonant peak tends to zero as b→0.

Under an electric potential U_{c} in a resonator domain 17, 17.1, the kinetic energies of electrons change, while the full energies remain constant and the resonance arises. Therefore, by varying a potential in the vicinity of the resonator 11.1, it is possible to control the energy of the resonance electrons.

What is claimed is:

1. A semiconductor device comprising a conduct structure to which is arranged
- contacts for a source and a drain,
a resonance region including at least two barrier regions, at least one resonator between the barrier regions and a control electrode and which resonance region is arranged between the contacts,
characterized in that,
the said conduct structure between the contacts is homogeneous,
the said barrier regions are formed of narrows arranged to the conduct structure.

2. A semiconductor device according to claim 1, characterized in that, the resonance region includes three barrier regions and two resonators in which one of the barrier regions is arranged between the resonators.

3. A semiconductor device according to claim 2, characterized in that, the control electrode is arranged to control the resonance level of one of the resonators and the resonance level of the other resonator is fixed.

4. A semiconductor device according to claim 1, characterized in that, the length (L₁) of the first resonator has been chosen so that at zero potential (U_{c}) at the control electrode the resonance level of the second resonator is higher than the maximal energy level at the source (E_{F1}) and drain (E_{F2}) contacts.

5. A semiconductor device according to claim 2, characterized in that, the lengths (L₁, L₂) of resonators are arranged in such a way that the resonance levels of the resonators differ from each other in an established manner.

6. A semiconductor device according to claim 3, characterized in that, the potential (U_{c}) at the control electrode and the voltage difference (U_{sd}) across the source and the drain contacts have been chosen so that the resonance level of the first resonator and the resonance level of the second resonator are lower than the maximal energy level (E_{F1}) at the source contact and higher than the maximal energy level (E_{F2}) at the drain contact.

7. A semiconductor device according to claim 1, characterized in that, in connection with the control electrode is arranged a contact for supplying a control potential (U_{c}) to the resonance region in order to change the resonance level of the resonance region.

8. A semiconductor device according to claim 2, characterized in that, the geometry (L₁, L₂) of the resonators is arranged in such a manner that the resonance energy levels of the resonators are lower than the maximum energy level (E_{F1}) at the source contact and higher than the maximum energy level (E_{F2}) at the drain contact.

9. A high frequency integrated circuit comprising a semiconductor device according to claim 1.

10. A high frequency integrated circuit comprising a semiconductor device according to claim 2.

11. A high frequency integrated circuit comprising a semiconductor device according to claim 3.

12. A high frequency integrated circuit comprising a semiconductor device according to claim 4.

13. A high frequency integrated circuit comprising a semiconductor device according to claim 5.

14. A high frequency integrated circuit comprising a semiconductor device according to claim 6.

15. A high frequency integrated circuit comprising a semiconductor device according to claim 7.

16. A high frequency integrated circuit comprising a semiconductor device according to claim 8.

17. Method to control a state of a semiconductor device comprising the steps of
providing a homogeneous conduct structure including contacts for a source and a drain of electrons and
providing a resonance region including at least two barrier regions, at least one resonator between the barrier regions and a control electrode and which resonance region is arranged between the contacts in order to control a resonant tunneling of the electrons having transversal and longitudinal motion components,
characterized in that, the longitudinal motion component of the electrons is prevented by the barrier regions.

18. Method to manufacture a semiconductor device comprising the steps of
providing a homogeneous conduct structure including contacts for a source and a drain of electrons and
providing a resonance region including at least two barrier regions, at least one resonator between the barrier regions and a control electrode and which resonance region is arranged between the contacts,
characterized in that, the barrier regions are arranged by providing the narrows to the homogeneous conduct structure.
